(19) United States
(12) Patent Application Publication
(10) Pub. No.: US 2012/0042944 A1
(43) Pub. Date: Feb. 23, 2012

(54) PHOTOVOLTAIC PANEL WITH FLEXIBLE SUBSTRATE AND OPTICAL PRISM LAYER

(75) Inventors: Chih-He YEN, Hong Kong (HK); Stephen Yau-Sang Cheng, Hong Kong (HK)

(73) Assignee: Du Pont Apollo Limited, Hong Kong (HK)

(21) Appl. No.: 13/209,462

(22) Filed: Aug. 15, 2011

Related U.S. Application Data
(60) Provisional application No. 61/375,880, filed on Aug. 23, 2010.

(51) Int. Cl. H01L 31/0232; H01L 31/0216

(52) U.S. Cl. 136/256; 136/259

(57) ABSTRACT

A photovoltaic panel includes a flexible substrate, an optical prism layer, and a photoelectric layer disposed between the plastic flexible substrate and the optical prism layer. The optical prism layer includes a transparent layer and a plurality of prisms attached to the transparent layer and disposed between the transparent layer and photoelectric layer.

### RELATED APPLICATIONS

This application claims priority to U.S. Provisional Application Ser. No. 61/375,880, filed Aug. 23, 2010, which is herein incorporated by reference

### BACKGROUND

1. Field of Invention

The present invention relates to a photovoltaic panel. More particularly, the present invention relates to a photovoltaic panel to be used in a portable electronic device and a home appliance.

2. Description of Related Art

A conventional photovoltaic panel is costly due to the multiple manufacturing steps and expensive material to meet harsh environmental requirement. For example, a transparent front glass is used to protect from the environment. A transparent and conductive top layer or grid is used to collect electrical currents and carry them away. Various intermediate processing steps, e.g. laser scribing and depositions to interconnect strips solar cells, annealing steps to activate or complete certain components; lamination to attach encapsulation; glass or other substrates handling, cleaning and heating, add more costs to a photovoltaic panel manufacturing.

However, the costly photovoltaic panel is to be used in a complete outdoor environment. For a portable electronic device and a home appliance, the above-mentioned photovoltaic panel is too expensive to be applied in an electronic device. Therefore, an efficiency-enhanced and cost-effective photovoltaic panel is required for portable devices and home appliances.

### SUMMARY

It is therefore an objective of the present invention to provide an efficiency-enhanced and cost-effective photovoltaic panel.

In accordance with the foregoing and other objectives of the present invention, a photovoltaic panel includes a flexible substrate, an optical prism layer, and a photoelectric layer disposed between the plastic flexible substrate and the optical prism layer. The optical prism layer includes a transparent layer and a plurality of prisms attached to the transparent layer and disposed between the transparent layer and photoelectric layer.

According to an embodiment disclosed herein, the transparent layer includes polycarbonate or polyester.

According to another embodiment disclosed herein, each of the prisms includes a triangular prism.

According to another embodiment disclosed herein, the prism comprises a round prism tip.

According to another embodiment disclosed herein, the photovoltaic panel further includes a first electrically conductive layer disposed between the photoelectric layer and the optical prism layer, and a second electrically conductive layer disposed between the photoelectric layer and the flexible substrate.

According to another embodiment disclosed herein, the photovoltaic panel further includes two conductive ribbons attached to be respectively connected with the electrically conductive layers for outputting electrical current.

According to another embodiment disclosed herein, the photovoltaic panel further includes an adhesive layer disposed between the optical prism layer and the electrically conductive layer.

According to another embodiment disclosed herein, the adhesive layer comprises a thickness ranging from about 10 μm to about 15 μm.

According to another embodiment disclosed herein, each of the prisms is made from acrylic resin.

According to another embodiment disclosed herein, each of the prisms has an apex angle ranging from about 70 degrees to about 115 degrees.

According to another embodiment disclosed herein, the prisms have a prism pitch ranging from about 50 μm to about 80 μm.

According to another embodiment disclosed herein, each of the prisms has a prism thickness ranging from about 30 μm to about 50 μm.

According to another embodiment disclosed herein, the transparent layer has a thickness ranging from about 120 μm to about 150 μm.

According to another embodiment disclosed herein, the optical prism layer has a thickness ranging from about 150 μm to about 200 μm.

According to another embodiment disclosed herein, the flexible substrate includes a plastic sheet of a thickness ranging from about 0.3 mm to about 2 mm.

According to another embodiment disclosed herein, the flexible substrate includes a metal sheet of a thickness ranging from about 0.1 mm to about 0.6 mm.

According to another embodiment disclosed herein, the prism includes a sharp prism tip.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a cross-sectional view of a photovoltaic panel according to one preferred embodiment of this invention;

FIG. 2 illustrates a cross-sectional view of a photovoltaic panel according to another preferred embodiment of this invention;

FIG. 3 illustrates a cross-sectional view of an optical prism layer according to another preferred embodiment of this invention;

FIG. 4 illustrates a perspective view of the optical prism layer in FIG. 1;

FIG. 5 illustrates a cross-sectional view of an optical prism layer according to yet another preferred embodiment of this invention; and

FIG. 6 illustrates a diagram to explain how the optical prism layer enhances the incident light intensity and reduces the reflection lose.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

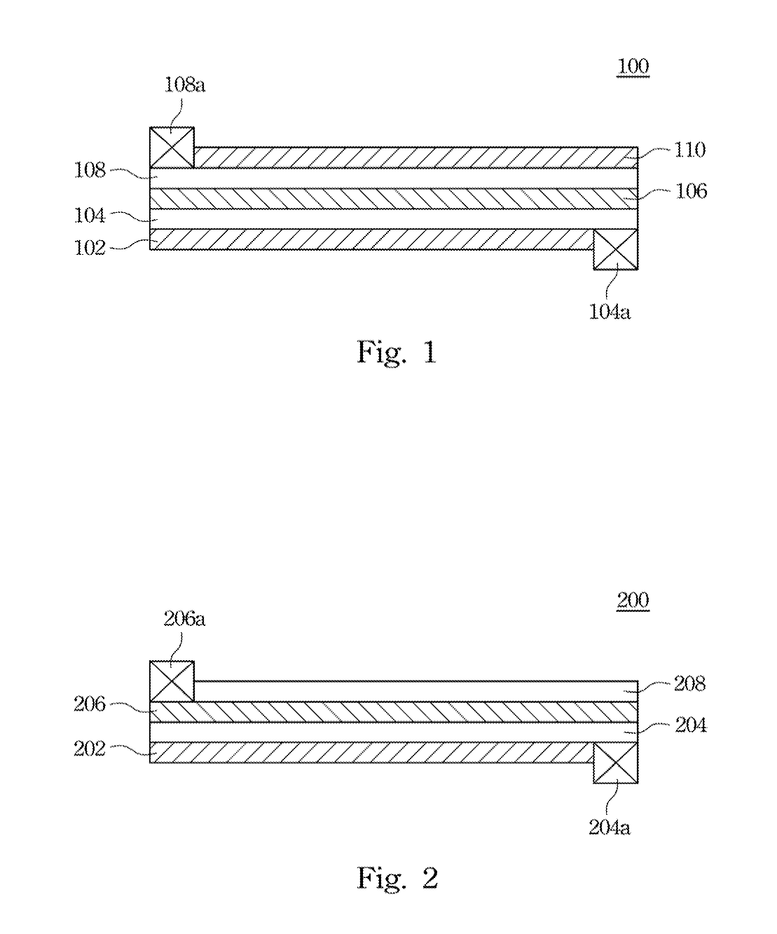

FIG. 1 illustrates a cross-sectional view of a photovoltaic panel according to one preferred embodiment of this invention. Instead of using high-cost material to protect a photoelectric layer to meet harsh environment requirement, the photovoltaic panel 100 herein basically has its photoelectric layer 106 secured between a flexible substrate 102 and an optical prism layer 110. The flexible substrate 102 permits the photovoltaic panel 100 to be bendable such that the photovoltaic panel 100 can be used on portable devices and home appliances. The optical prism layer 110 is to enhance the photovoltaic panel's efficiency for converting solar radiation into electricity. Besides, the photovoltaic panel 100 should at least includes an electrically conductive layer 104 and an transparent electrically conductive layer 108 for collecting electricity from the photoelectric layer 106, which converts solar radiation into electricity. The electrically conductive layer 104 is sandwiched between the flexible substrate 102 and the photoelectric layer 106. In this embodiment, the flexible substrate 102 is a plastic sheet of a thickness ranging from about 0.3 mm to about 2 mm. The electrically conductive layer 108 is sandwiched between the optical prism layer 110 and the photoelectric layer 106. Two conductive ribbons 108a and 104a are attached to be respectively connected with the electrically conductive layers 104 and 108 for outputting electrical current.

FIG. 2 illustrates a cross-sectional view of a photovoltaic panel according to another preferred embodiment of this invention. The difference between this embodiment and the embodiment of FIG. 1 lies in that the flexible substrate 202 is a metal substrate. The photovoltaic panel 200 basically has its photoelectric layer 204 secured between a flexible substrate 202 and an optical prism layer 208. The flexible substrate 202 permits the photovoltaic panel 200 to be bendable such that the photovoltaic panel 200 can be applicably used on portable devices and home appliances. The optical prism layer 208 is to enhance the photovoltaic panel's efficiency for converting solar radiation into electricity. Besides, the photovoltaic panel 200 should at least includes an transparent electrically conductive layer 206 for outputting electricity from the photoelectric layer 204, which converts solar radiation into electricity. The electrically conductive layer 206 is sandwiched between the optical prism layer 208 and the photoelectric layer 204. Since the flexible substrate 202 is a metal substrate, it can perform the same function, e.g. outputting electricity from the photoelectric layer 204, as the electrically conductive layer does, an extra electrically conductive layer is not necessary. In this embodiment, the flexible substrate 102 can be a metal sheet, e.g. an aluminum sheet, of a thickness ranging from about 0.1 mm to about 0.6 mm. Two conductive ribbons 204a and 206a are attached to be respectively connected with the flexible substrate 202 and the electrically conductive layer 206 for outputting electrical current.

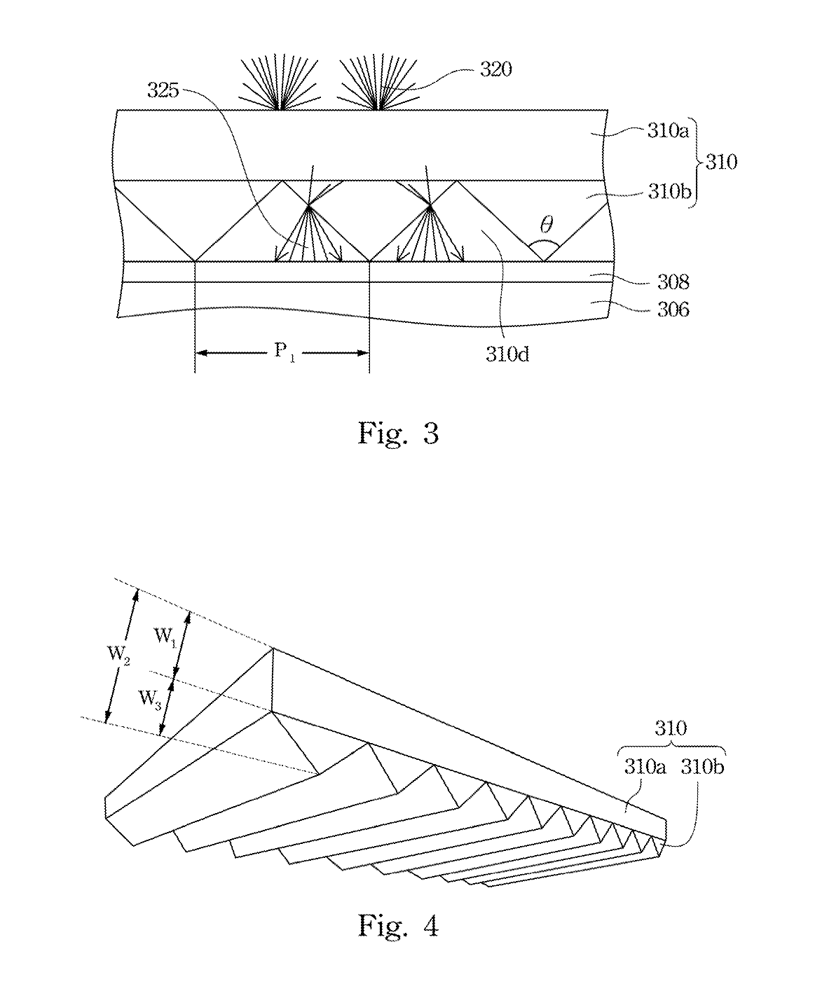

FIG. 3 illustrates a cross-sectional view of an optical prism layer according to another preferred embodiment of this invention. The optical prism layer 310 aims to collect more incident light 320 so as to enhance the photovoltaic panel's efficiency for converting solar radiation into electricity. The optical prism layer 310 basically includes a transparent layer 310a and a plurality of triangular prisms 310b attached under the transparent layer 310a. The triangular prisms 310b is able to direct the incident light 320 along the directions 325, thereby penetrating the layers under thereof, e.g. an adhesive layer 308, an electrically conductive layer 306 and a photoelectric layer (not illustrated in FIG. 3). The adhesive layer 308 is to fasten prism tips of the triangular prisms 310b to the electrically conductive layer 306. In this embodiment, the adhesive layer 308 has a thickness ranging from about 10 μm to about 15 μm. The thickness of adhesive layer 308 should be thick enough to firmly secure the triangular prisms 310b and be thin enough to leave air gaps 310d among the adhesive layer 308 and any adjacent-two triangular prisms 310b. If the adhesive layer 308 is not thin enough, the air gaps 310d may be filled with the adhesive, thereby causing the triangular prisms 310b to malfunction, i.e. unable to direct the incident light 320 along the directions 325 that is able to penetrate the layers under thereof. In this embodiment, each of the triangular prisms 310b has an apex angle θ ranging from about 70 degrees to about 115 degrees. Besides, the triangular prisms 310b has a prism pitch P₁ (which refers to an interval between the peaks of adjacent triangular prisms) ranging from about 50 μm to about 80 μm.

FIG. 4 illustrates a perspective view of the optical prism layer in FIG. 1. The optical prism layer 310 basically includes a transparent layer 310a and a plurality of triangular prisms 310b attached under the transparent layer 310a. In this embodiment, the transparent layer 310a can be made from but not limited to polycarbonate, polyester or a transparent material equipped with abrasive resistance and non-yellowing. Besides, the triangular prisms 310b can be made from but not limited to acrylic resin. The transparent layer 310a has a thickness Wranging from about 120 μm to about 150 μm. Each of the triangular prisms 310b has a prism thickness W₃ ranging from about 30 μm to about 50 μm. Thus, the optical prism layer 310 has a thickness W₂ ranging from about 150 μm to about 200 μm.

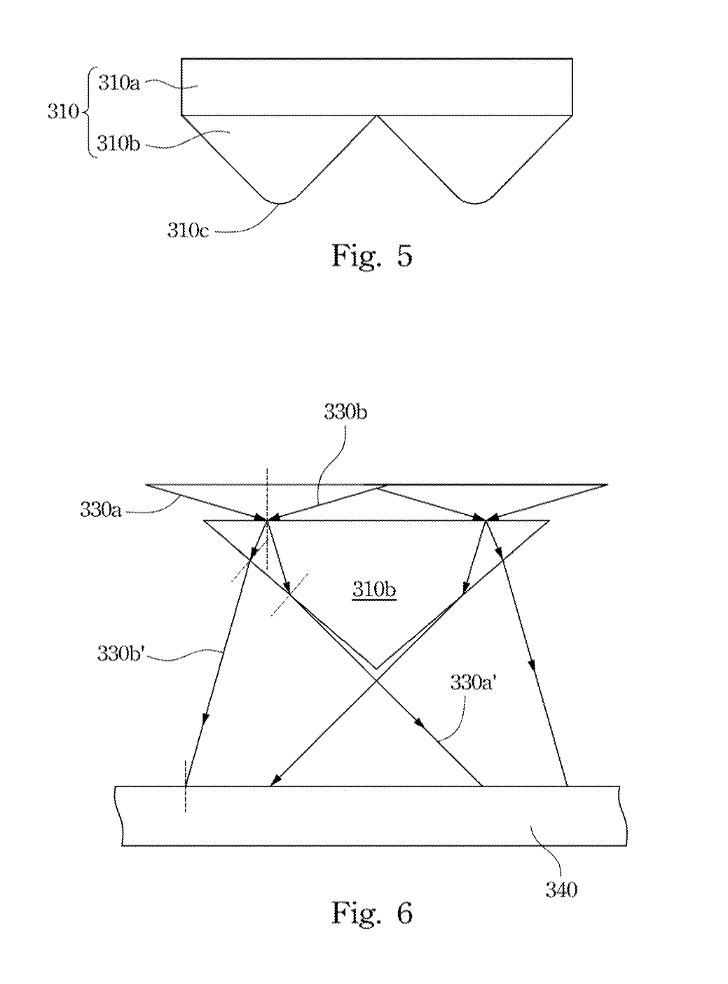

FIG. 5 illustrates a cross-sectional view of an optical prism layer according to yet another preferred embodiment of this invention. This embodiment is different from the embodiment illustrated in FIG. 3 in that the triangular prisms 310b have a round prism tip 310c. The round prism tip 310c is more easily secured by the adhesive layer than a sharp prism tip, which is illustrated in FIG. 3.

FIG. 6 illustrates a diagram to explain how the optical prism layer enhances the incident light intensity and reduces the reflection lose. As mentioned above, the triangular prism 310b aims to collect more incident light so as to enhance the photovoltaic panel's efficiency for converting solar radiation into electricity. particular, the triangular prism 310b directs an incident light 330a, which is reflected by a conventional glass of a photovoltaic panel and not used by a photoelectric layer of the photovoltaic panel, along a direction 330a′, thereby causing the incident light to easily penetrate an under layer 340, e.g. a photoelectric layer. Besides, the triangular prism 310b directs an incident light 330b, which is reflected by a conventional glass of a photovoltaic panel and not used by a photoelectric layer of the photovoltaic panel, along a direction 330b′, thereby causing the incident light to easily penetrate an under layer 340, e.g. a photoelectric layer. Therefore, a wider range of incident light, i.e. a range between the incident lights 330a and 330b, can be collected by means of the triangular prism 310b to enhance the incident light intensity and reduces the reflection lose.

According to the above-discussed embodiments, the photovoltaic panel disclosed herein has its photoelectric layer secured between a flexible substrate and an optical prism layer. The optical prism layer collects more incident light so as to enhance the photovoltaic panel's efficiency for converting solar radiation into electricity. The flexible substrate allows the photovoltaic panel to be bendable. In sum, the photovoltaic panel can be applicably used on portable devices and home appliances.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic panel comprising:
a flexible substrate;
an optical prism layer; and
a photoelectric layer disposed between the flexible substrate and the optical prism layer, wherein the optical prism layer comprises:
a transparent layer; and
a plurality of prisms attached to the transparent layer and disposed between the transparent layer and the photoelectric layer.

2. The photovoltaic panel of claim 1, wherein the transparent layer comprises polycarbonate or polyester.

3. The photovoltaic panel of claim 1, wherein each of the prisms comprises a triangular prism.

4. The photovoltaic panel of claim 3, wherein each of the prisms comprises a round prism tip.

5. The photovoltaic panel of claim 3, further comprising a first electrically conductive layer disposed between the photoelectric layer and the optical prism layer and a second electrically conductive layer disposed between the photoelectric layer and the flexible substrate.

6. The photovoltaic panel of claim 5, further comprising two conductive ribbons attached to be respectively connected with the electrically conductive layers for outputting electrical current.

7. The photovoltaic panel of claim 5, further comprising an adhesive layer disposed between the optical prism layer and the electrically conductive layer.

8. The photovoltaic panel of claim 7, wherein the adhesive layer comprises a thickness ranging from about 10 μm to about 15 μm.

9. The photovoltaic panel of claim 1, wherein each of the prisms comprises acrylic resin.

10. The photovoltaic panel of claim 1, wherein each of the prisms comprises an apex angle ranging from about 70 degrees to about 115 degrees.

11. The photovoltaic panel of claim 1, wherein the prisms comprise a prism pitch ranging from about 50 μm to about 80 μm.

12. The photovoltaic panel of claim 1, wherein each of the prisms comprises a prism thickness ranging from about 30 μm to about 50 μm.

13. The photovoltaic panel of claim I, wherein the transparent layer comprises a thickness ranging from about 120 μm to about 150 μm.

14. The photovoltaic panel of claim 1, wherein the optical prism layer comprises a thickness ranging from about 150 μm to about 200 μm.

15. The photovoltaic panel of claim 1, wherein the flexible substrate is a plastic sheet of a thickness ranging from about 0.3 mm to about 2 mm.

16. The photovoltaic panel of claim 1, wherein the flexible substrate is a metal sheet of a thickness ranging from about 0.1 mm to about 0.6 mm.

17. The photovoltaic panel of claim 1, wherein the prism comprises a sharp prism tip.
